(19) United States
(12) Patent Application Publication
(10) Pub. No.: US 2007/0085068 A1
(43) Pub. Date: Apr. 19, 2007

(54) Spin transfer based magnetic storage cells utilizing granular free layers and magnetic memories using such cells

(76) Inventors: Dmytro Apalkov, Framingham, MA (US); Zhitao Diao, Fremont, CA (US); Yunfei Ding, St. Paul, MN (US); Yiming Huai, Pleasanton, CA (US)

Correspondence Address: SAWYER LAW GROUP LLP, P O BOX 51418, PALO ALTO, CA, 94303, US

(21) Appl. No.: 11/251,428

(22) Filed: Oct. 14, 2005

(51) Int. Cl. H01L 47/00; H01L 29/00

(52) U.S. Cl. 257/1

(57) ABSTRACT

A method and system for providing a magnetic element and a memory incorporating the magnetic element is described. The method and system for providing the magnetic element include providing a pinned layer, a spacer layer, and a free layer. The free layer includes granular free layer having a plurality of grains in a matrix, the spacer layer residing between the pinned layer and the free layer. The magnetic element is configured to allow the granular free layer to be switched due to spin-transfer when a write current is passed through the magnetic element.

### FIELD OF THE INVENTION

The present invention relates to magnetic memory systems, and more particularly to a method and system for providing memory cells and accompanying circuitry for use in a magnetic memory having cells that can be switched using a spin-transfer effect.

### BACKGROUND OF THE INVENTION

FIGS. 1 and 2 depict conventional magnetic elements 10 and 10′. Such conventional magnetic elements 10/10′ can be used in non-volatile memories, such as MRAM. The magnetization state of the magnetic elements 10/10′ can also be switched using the spin-transfer effect. Spin-transfer based switching is desirable because spin-transfer is a localized phenomenon that may be used to write to a cell without inadvertently writing to neighboring cells. Consequently, it would be desirable to use the conventional magnetic elements 10/10′ in a magnetic memory, such as MRAM, that employs spin-transfer switching.

The conventional magnetic element 10 is a spin valve and includes a conventional antiferromagnetic (AFM) layer 12, a conventional pinned layer 14, a conventional nonmagnetic spacer layer 16 and a conventional free layer 18. Other layers (not shown), such as seed or capping layer may also be used. The conventional pinned layer 14 and the conventional free layer 18 are ferromagnetic. The ferromagnetic layers 14 and 18 typically include FeCo, FeCoB, Permalloy, Co or a combination of several layers. For example, the conventional pinned layer 14 may include two ferromagnetic layers antiferromagnetically coupled through a thin Ru layer via RKKY exchange interaction -forming a synthetic antiferromagnetic (SAF) layer. The conventional free layer 18 is typically thinner than the conventional pinned layer 14, and has a changeable magnetization 19. The conventional nonmagnetic spacer layer 16 is conductive. The magnetization of the conventional pinned layer 14 is fixed, or pinned, in a particular direction, typically by an exchange-bias interaction with the AFM layer 12.

The conventional magnetic element 10′ depicted in FIG. 2 is a spin tunneling junction. Portions of the conventional spin tunneling junction 10′ are analogous to the conventional spin valve 10. However, the conventional barrier layer 16′ is an insulator that is thin enough for electrons to tunnel through in a conventional spin tunneling junction 10′. Note that only a single spin valve 10 is depicted, one of ordinary skill in the art will readily recognize that dual spin valves including two pinned layers and two nonmagnetic layers separating the pinned layers from the free layer can be used. Similarly, although only a single spin tunneling junction 10′ is depicted, one of ordinary skill in the art will readily recognize that dual spin tunneling including two pinned layers and two barrier layers separating the pinned layers from the free layer, can be used. More recently, structures having two pinned layers and two layers, one barrier and one conductive, separating the pinned layers from the free layer have been developed, particularly for use when exploiting spin-transfer in programming.

Typically, a shape anisotropy of the conventional free layer 18/18′ determines two possible stable states for the device: a low resistance parallel (P) state having the magnetization 19/19′ of the conventional free layer 18/18′ aligned in the direction of the magnetization of the conventional pinned layer 14/14′ and a high resistance anti-parallel (AP) state having the magnetization 19/19′ of the conventional free layer 18/18′ aligned in a direction opposite to the magnetization of the conventional pinned layer 14/14′. This shape anisotropy is typically provided by the magnetostatic force generated by the elliptical shape 11/11′. The shape anisotropy favors a magnetization 19/19′ that is substantially parallel to the long axis, 1, of the ellipse.

The reading of the magnetic element 10/10′ state is done by measuring the resistance of the magnetic element 10/10′. To sense the resistance of the conventional magnetic element 10/10′, current is driven through the conventional magnetic element 10/10′. Typically in memory applications, current is driven in a CPP (current perpendicular to the plane) configuration, perpendicular to the layers of conventional magnetic element 10/10′ (up or down, in the z-direction as seen in FIG. 1 or 2). Based upon the change in resistance, typically measured using the magnitude of the voltage drop across the conventional magnetic element 10/10′, the resistance state and, therefore, the data stored in the conventional magnetic element 10/10′ can be determined.

The switching between the P and AP states may be achieved through spin-transfer. This is accomplished by passing a write current in the CPP configuration. The write current is greater than that used in reading in order to avoid in advertently writing to the magnetic element 10/10′. When current is driven from the conventional free layer 18/18′ to the conventional pinned layer 14/14′, electrons travel from the conventional pinned layer 14/14′ to the conventional free layer 18/18′. When the electrons are passed through the conventional pinned layer 14/14′, electrons carrying the current become spin-polarized with their spins preferentially pointing along the magnetization of the conventional pinned layer 14/14′. As the spin-polarized electrons enter the conventional free layer 18/18′, they exert a torque on the magnetization 19/19′ of the free layer 18/18′. This spin-transfer torque may generate spin waves and/or complete switching of the magnetization 19/19′ of the free layer 18/18′ to be parallel to that of the conventional pinned layer 14/14′. When current is driven in the opposite direction, electrons travel from the free layer 18/18′ to the conventional pinned layer 14/14′. Those electrons having their spins polarized antiparallel to the magnetization of the conventional pinned layer 14/14′ preferentially reflect back to the conventional free layer 18/18′. These spin polarized electrons may generate spin waves and/or complete switching of the magnetization 19/19′ of the free layer 18/18′ to be anti-parallel to that of the conventional pinned layer 14/14′.

Although the conventional magnetic elements 10/10′ can be used to record (or write) data in an MRAM using spin-transfer based switching, one of ordinary skill in the art will readily recognize that there are drawbacks. One primary issue includes the high amplitude of the current density required to switch the magnetization 19/19′ of the conventional free layer 18/18′ in nanosecond regime. A measure of the current density in the magnetic element 10/10′ is given by on-axis magnetization instability current density for a monodomain small particle under the influence of spin-transfer torque. This instability current density is given by:

$${J}_{c 0} = \frac{2 e α {M}_{S} {t}_{F} ( H + {H}_{K} + \frac{{H}_{d}}{2} )}{ℏη} , \qquad ( 1 )$$

where e is electron charge, α is the Gilbert damping constant, M_{S} is the saturation magnetization, t_{F} is the thickness of the free layer, H is the applied field, H_{K} is the effective uniaxial anisotropy field of the conventional free layer 18/18′ (including shape and intrinsic anisotropy contributions), H_{d} is the out-of-plane demagnetizing field, which for a thin ferromagnetic film is close to 4πM_{S}, ℏ is the reduced Planck's constant, and η is the spin-transfer efficiency related to polarization factor of the incident current. At the instability current density, the initial position of the magnetization 19/19′ of the conventional free layer 18/18′ along the easy axis (long axis, 1) becomes unstable and may commence precession. As the current is increased above the instability current density, the amplitude of this precession increases until the magnetization 19/19′ is switched into the other state. For switching of the conventional free layer magnetization 19/19′ in nanosecond regime, the required current switching current is several times greater than the instability current J_{c0}. Although several techniques and materials have been proposed to decrease the switching current, the high switching current density remains a significant issue for spin-transfer based MRAM.

In addition, the thermal stability of the conventional magnetic element 10/10′ may be less than desired. The thermal stability of the magnetization 19/19′ of the conventional free layer 18/18′ depends upon its anisotropy field, Hₖ, which includes the shape anisotropy of the conventional free layer 18/18′. The thermal stability factor for the conventional free layer 18/18′ is: Δ=H_{K}M_{S}V/2k_{B}T, where k_{B} is Boltzmann constant, V is the volume of the free layer 18/18′, and T is the absolute operating temperature. In order to achieve the data retention over long period of time (approximately ten years) the required value of the thermal stability factor is approximately sixty. The thermal stability of conventional free layer 18/18′ is thus greatly dependent on the shape and lateral dimensions of the conventional magnetic element 10/10′. These features may not be well controlled and are generally expected to vary due to fabrication process. Consequently, some of the cells in a device employing the conventional magnetic element 10/10′ may have the thermal stability factor less than required, resulting in false bits or device failure over time. In addition, in spin-transfer switching, the switching current is related to the thermal stability factor and pulse width τ:

$${J}_{c} = {J}_{c 0} [ 1 - \frac{1}{Δ} {( 1 + \frac{H}{{H}_{K}} )}^{- 2} ln ( \frac{τ}{{τ}_{0}} ) ] \qquad ( 2 )$$

where τ₀ is the inverse of the activation frequency. Therefore variation in thermal stability factor Δ from cell to cell will result in variation of switching current J_{c} from cell to cell. Consequently, issues such as accidental recording during reading for a cell with small Δ or unwritten cells during recording for a cell with high Δ may be encountered.

Consequently, the conventional magnetic element 10/10′ may have the thermal stability factor that is different from what is desired, resulting in false bits or device failure over time.

Accordingly, what is needed is a system and method for providing a magnetic memory element that can be switched using a lower current density. The present invention addresses such a need.

### BRIEF SUMMARY OF THE INVENTION

The present invention provides a method and system for providing a magnetic element and a memory incorporating the magnetic element. The method and system for providing the magnetic element include providing a pinned layer, a spacer layer, and a free layer. The free layer includes granular free layer having a plurality of grains in a matrix, the spacer layer residing between the pinned layer and the free layer. The magnetic element is configured to allow the granular free layer to be switched due to spin-transfer when a write current is passed through the magnetic element.

According to the method and system disclosed herein, the present invention provides magnetic elements that are programmable through the phenomenon of spin-transfer by a lower write current driven through the magnetic elements.

### BRIEF DESCRIPTION OF SEVERAL VIEWS OF THE DRAWINGS

FIG. 1 is a diagram of a conventional magnetic element, a spin valve.

FIG. 2 is a diagram of another conventional magnetic element, a spin tunneling junction.

FIG. 3 is a diagram of one embodiment in accordance with the present invention of a magnetic element capable of being switched using spin-transfer and including a granular free layer.

FIG. 4 is a diagram of one embodiment in accordance with the present invention of a granular free layer.

FIG. 5 is a diagram of another embodiment in accordance with the present invention of a magnetic element capable of being switched using spin-transfer and including a granular free layer.

FIG. 6 is a diagram of one embodiment in accordance with the present invention of a granular free layer during switching.

FIG. 7 is a diagram of one embodiment in accordance with the present invention of a granular free layer during switching.

FIG. 8 is a diagram of one embodiment in accordance with the present invention of a granular free layer during switching.

FIG. 9 is a diagram of one embodiment in accordance with the present invention of a granular free layer during switching.

FIG. 10 is a diagram of a conventional free layer during switching.

FIG. 11 is a diagram of a conventional free layer during switching.

FIG. 12 is a diagram of a conventional free layer during switching.

FIG. 13 is a diagram of another embodiment in accordance with the present invention of a magnetic element capable of being switched using spin-transfer and including a granular free layer.

FIG. 14 is a diagram of another embodiment in accordance with the present invention of a magnetic element capable of being switched using spin-transfer and including a granular free layer.

FIG. 15 is a diagram of another embodiment in accordance with the present invention of a magnetic element capable of being switched using spin-transfer and including a granular free layer.

FIG. 16 is a diagram of another embodiment in accordance with the present invention of a magnetic element capable of being switched using spin-transfer and including a granular free layer.

FIG. 17 is a flow chart depicting one embodiment of a method in accordance with the present invention for providing one embodiment of a magnetic element capable of being switched using spin-transfer and including a granular free layer.

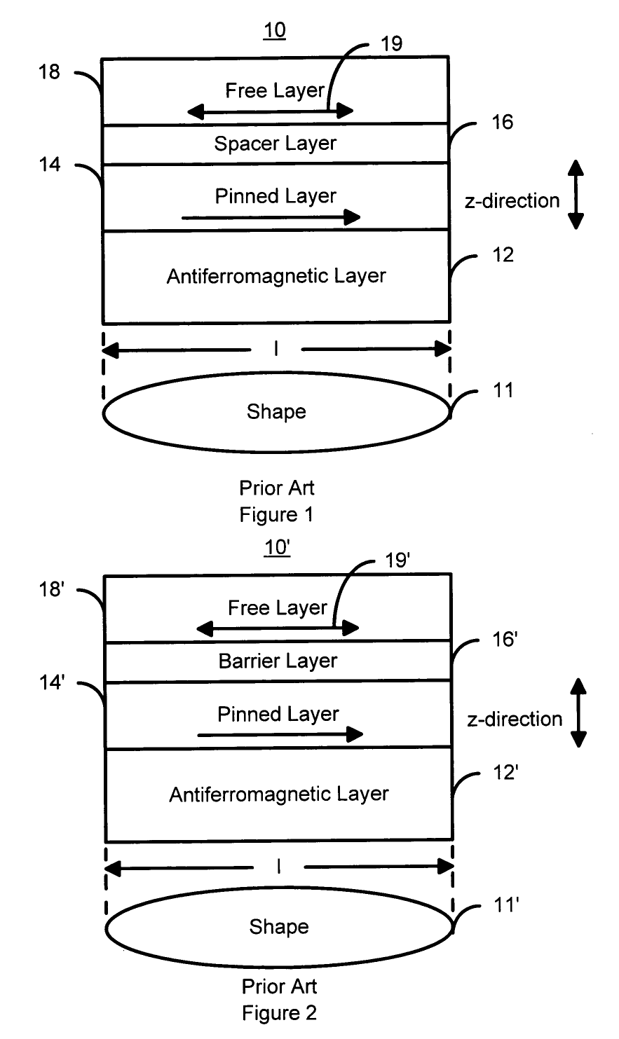

### DETAILED DESCRIPTION OF THE INVENTION

The present invention relates to a magnetic memory. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

The present invention provides a method and system for providing a magnetic element and a memory incorporating the magnetic element. The method and system for providing the magnetic element include providing a pinned layer, a spacer layer, and a free layer. The free layer includes granular free layer having a plurality of grains in a matrix, the spacer layer residing between the pinned layer and the free layer. The magnetic element is configured to allow the granular free layer to be switched due to spin-transfer when a write current is passed through the magnetic element.

The present invention will be described in terms of a particular magnetic memory and a particular magnetic element having certain components. However, one of ordinary skill in the art will readily recognize that this method and system will operate effectively for other magnetic memory elements having different and/or additional components and/or other magnetic memories having different and/or other features not inconsistent with the present invention. The present invention is also described in the context of current understanding of the spin-transfer phenomenon, as well as spin polarization due to interfaces with barrier layers. Consequently, one of ordinary skill in the art will readily recognize that theoretical explanations of the behavior of the method and system are made based upon this current understanding of spin-transfer and spin polarization. One of ordinary skill in the art will also readily recognize that the method and system are described in the context of a structure having a particular relationship to the substrate. However, one of ordinary skill in the art will readily recognize that the method and system are consistent with other structures. In addition, the method and system are described in the context of certain layers being synthetic and/or simple. However, one of ordinary skill in the art will readily recognize that the layers could have another structure. Furthermore, the present invention is described in the context of magnetic elements having particular layers. However, one of ordinary skill in the art will readily recognize that magnetic elements having additional and/or different layers not inconsistent with the present invention could also be used. Moreover, certain components are described as being ferromagnetic. However, as used herein, the term ferromagnetic could include ferrimagnetic or like structures. Thus, as used herein, the term “ferromagnetic” includes, but is not limited to ferromagnets and ferrimagnets. The present invention is also described in the context of single elements. However, one of ordinary skill in the art will readily recognize that the present invention is consistent with the use of magnetic memories having multiple elements, bit lines, and word lines.

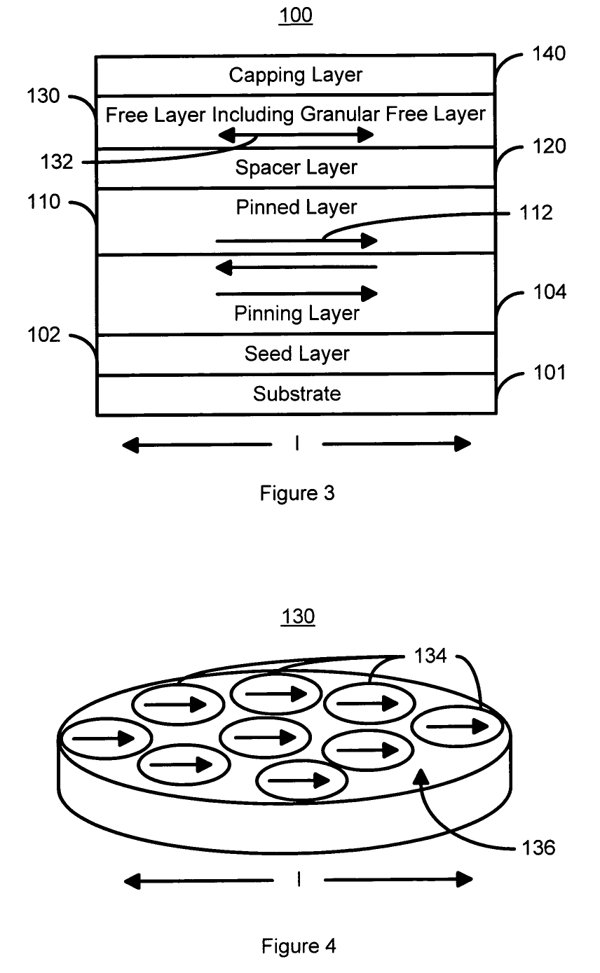

FIG. 3 is a diagram of one embodiment of a magnetic element 100 capable of being switched using spin-transfer and including a granular free layer. The magnetic element 100 includes a pinned layer 110, a spacer layer 120, and a free layer 130. In addition, the magnetic element 100 may include a seed layer 102, a pinning layer 104, and a capping layer 140. Also depicted is a substrate 101 on which the magnetic element 100 is formed.

The pinning layer 104 is preferably an antiferromagnetic (AFM) layer, for example including PtMn and/or IrMn. The pinning layer 104 is used to pin the magnetization 112 of the pinned layer 110 in a desired direction. However, in another embodiment, another mechanism might be used for pinning the magnetization 112 in the desired direction.

The pinned layer 110 preferably includes at least one of Co, Ni, and Fe. The pinned layer 110 has its magnetization 112 pinned in the desired direction, which is preferably along the easy axis of the free layer 130. The pinned layer 110 is shown as a simple layer. However, the pinned layer 110 may be a multilayer. For example, the pinned layer 110 may be an SAF layer including two ferromagnetic layers separated by a thin non-magnetic conductive layer, such as Ru. The ferromagnetic layers for such an SAF would have their magnetizations aligned antiparallel.

The spacer layer 120 is nonmagnetic may be conductive, insulating, or a nano-oxide layer. For example, if the spacer layer 120 is conductive, conductive materials such as Cu might be used. If the spacer layer 120 is insulating, the spacer layer 120 is thin. Consequently, current carriers may tunnel through the spacer layer 120. Insulating materials used may include materials such as alumina and/or crystalline MgO.

The free layer 130 is configured to be switched using spin-transfer. In addition, the free layer 130 includes a granular free layer. In the embodiment shown, the free layer 130 consists of a granular free layer. FIG. 4 is a diagram of one embodiment in accordance with the present invention of the granular free layer 130. Note that although the granular free layer 130 is depicted as having an elliptical shape, in another embodiment, another shape may be used. Referring to FIGS. 3 and 4, the granular free layer 130 includes grains 134 in a matrix 136. The magnetization 132 of the granular free layer 130 is aligned with the easy axis, 1, of the granular free layer 130. The magnetization 132 of the granular free layer 130 is established by the net magnetization of the grains 134. Similarly, the easy axis of the granular free layer 130 is established by the grains 134. Thus, in a preferred embodiment, the grains 134 in the granular free layer 130 are be elongated along the easy axis to create uniaxial anisotropy along this direction. Thus, as shown in FIG. 4, the grains 134 are longer in a direction parallel to the easy axis, 1. Thus, the aspect ratio of the grains 134 is greater than 1. In a preferred embodiment, the aspect ratio of the grains is at least two and not greater than ten. However, in an alternate embodiment, the aspect ratio may be greater than ten, for example to maintain the thermal stability of the grains 134. The longitudinal size (length parallel to the easy axis) of the grains 134 is preferably from five to fifty nanometers. The exchange stiffness constant for the exchange interaction between the grains 134 is preferably less than the intra-granular exchange stiffness constant. Consequently, the magnetization of the neighboring grains 134 may have different orientation during the spin-transfer switching, described below. In addition, note that the discussion above is in the context of all of the grains 134. However, one of ordinary skill in the art will readily recognize that the description above, such as the aspect ratio, need not apply to all grains. In one embodiment, the discussion above applies to a majority of the grains. In a preferred embodiment, the discussion above applies to substantially all of the grains.

The granular free layer 130 can be formed using a variety of types of materials. In general, the material(s) are used for the grains 134 are immiscible with the material(s) used for the matrix 136. The granular free layer 130 might be metallic-based (having a metallic matrix), oxide-based (having an oxide matrix), multilayer-granular, and/or may be formed of other materials. For example, if the granular free layer 130 is metallic based, the granular free layer 130 may include TMₓNM₍₁₀₀₋ₓ₎, where the TM includes at least one of Ni, Fe, and Co, NM includes at least one of Cu, Ag, and Au, and x is at least five and not more than fifty atomic percent. Similarly, if the granular free layer 130 is metallic based, the granular free layer 130 may include (TM1_{y}TM2_{(1-y))x}NM₍₁₀₀₋ₓ₎ where the TM1 includes at least one of Ni, Fe, and Co, the TM2 is at least one of Ni, Fe, Co, NM includes at least one of Cu, Ag, Au, x is at least five and not more than fifty atomic percent, and y is at least 0.05 and not more than 0.95. If the granular free layer 130 is metallic based, the granular free layer 130 may include the granular free layer includes (CoFeNi)ₓNM₍₁₀₀₋ₓ₎, where the NM includes at least one of Cu, Ag, and Au and x is at least five and not more than fifty atomic percent. If the granular free layer 130 is oxide based, the granular free layer 130 may include TM_{y}Oxide_{(100-y)}, where the TM includes at least one of Ni, Fe, Co, the Oxide includes at least one of AlOₓ, SiOₓ, TiOₓ, TaOₓ, ZrOₓ, HfOₓ, MgO, and y is at least five and not more than fifty atomic percent. Similarly, if the granular free layer 130 is oxide based, the granular free layer 130 may include (TM1_{z}TM2_{(1-z)})_{y}Oxide_{(100-y)}, where TM1 is at least one of Ni, Fe, and Co, TM2 is at least one of Ni, Fe, Co, the Oxide includes at least one of AlOₓ, SiOₓ, TiOₓ, TaOₓ, ZrOₓ, HfOₓ, and MgO; y is at least five and not more than fifty atomic percent and z is at least 0.05 and not more than 0.95. If the granular free layer 130 is oxide based, the granular free layer 130 may include (CoFeNi)_{y}Oxide_{(100-y)}, where the Oxide includes at least one of AlOₓ, SiOₓ, TiOₓ, TaOₓ, ZrOₓ, HfOₓ, and MgO, and y is at least five and not more than fifty atomic percent.

In addition, the granular free layer 130 may be a multilayer. In such an embodiment, the granular free layer 130 may include a bilayer that might be repeated multiple times. In such an embodiment, the bilayer includes a first layer and a second layer. The first layer includes a transition metal at a first thickness, while the second layer is nonmagnetic and has a second thickness. In a preferred embodiment, the first thickness is at least five Angstroms and not more than one hundred Angstroms and wherein the second thickness is at least ten Angstroms and not more than one hundred Angstroms. In such an embodiment, the first layer includes a transition metal. Thus, the first layer may be a transition metal alloy. The second layer includes at least one of Cu, Ag, Au, AlOₓ, SiOₓ, TiOₓ, TaOₓ, ZrOₓ, HfOₓ, and MgO that forms granular material as described above via solid diffusion process. In addition, note that the granular free layer may include materials such as CrFe. Moreover, certain of the granular systems described above may have a perpendicular anisotropy. For example, the use of CoFe—HfO, CoFe—AgCu, CoPt—SiO₂ or CoPtCr—SiO₂ for the granular layer 130 exhibit a perpendicular anisotropy that may aid in increasing the spin-transfer effect. The granular free layer 130 may also be CrFe.

The granular free layer 130 may include any combination of the materials and layers described above. For example, if the granular free layer 130 includes a metallic matrix (either as described above or as part of the multilayer described above), the matrix may be a binary or ternary alloy for example of Cu, Ag, and Au. An oxide matrix can be a mixture of two or more oxides out of those above.

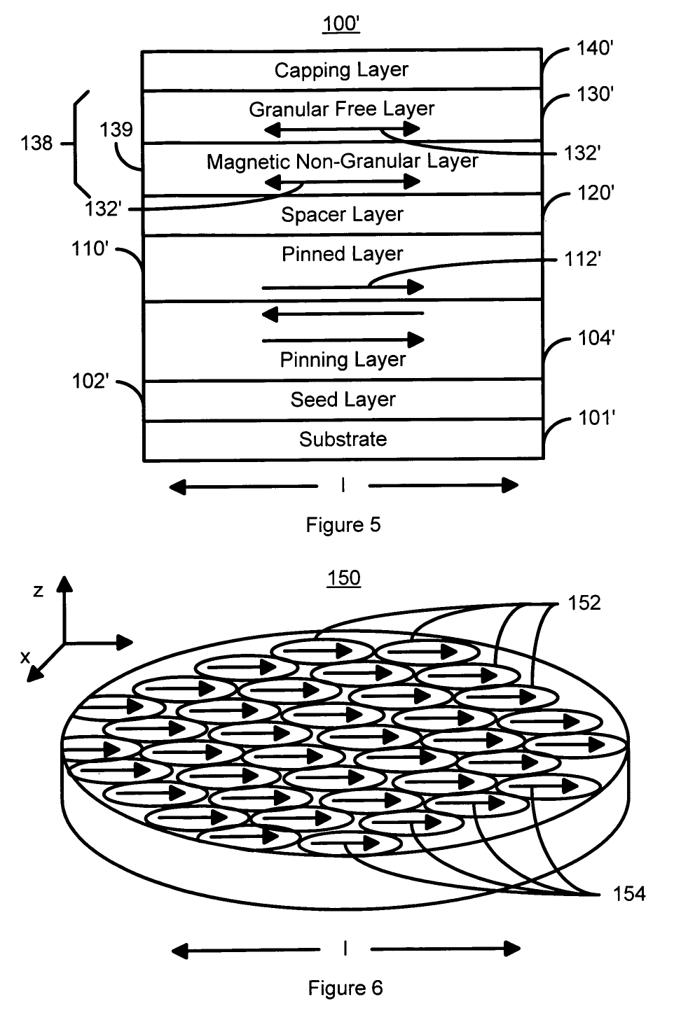

FIG. 5 is a diagram of another embodiment of a magnetic element 100′ capable of being switched using spin-transfer and including a granular free layer. The magnetic element 100′ is analogous to the magnetic element 100. Consequently, analogous components are labeled similarly. Thus, the magnetic element 100′ includes layers 102′, 104′, 110′, 130′, and 140′that are analogous to the layers 102, 104, 110, 130, and 140, respectively.

The granular free layer 130′ can be switched using spin-transfer and is part of the free layer 138. The free layer 138 thus includes the granular free layer 130′ and at least one other layer. In the embodiment shown, the other layer is a magnetic layer 139. The magnetic layer 139 can also be switched using spin-transfer and is not a granular layer. Consequently, the magnetic layer 139 preferably has the lateral dimensions, along the long axis, 1, of the free layer 130′ that are preferably less than two hundred nanometers. In a preferred embodiment, the magnetic layer 139 includes at least one of CoFe and CoFeB. Also in a preferred embodiment, the magnetic layer 139 has a thickness from five Angstroms to ten Angstroms. Such a magnetic layer 139 may enhance the tunneling magnetoresistance.

In operation, the magnetization of the granular free layer 130 and 130′ can be switched utilizing spin-transfer. In a preferred embodiment, for the free layer 138 incorporating the granular free layer 130′, the layer 139 may also be switched using spin-transfer. To describe the operation of a granular free layer such as the layers 130 and 130′, refer to FIGS. 6-9, depicting one embodiment of a granular free layer 150 during switching. Note that although the granular free layer 150/150′ is depicted as having an elliptical shape, in another embodiment, another shape may be used. Although the discussion is for the granular free layer 150, the granular free layers 130 and 130′ switch in an analogous manner. FIG. 6 is a diagram of one embodiment in accordance with the present invention of a granular free layer 150 with magnetizations 154 for grains 152 in an equilibrium state. Consequently, the magnetizations 154 are generally aligned. Note that although the magnetizations are depicted in FIG. 6 as being aligned, there may be some variation. Furthermore, although the magnetizations 154 are generally aligned, the magnetizations 154 of the neighboring grains 152 are not exchange bound as strongly as the intrinsic exchange within the grain or exchange in a ferromagnetic layer. Stated differently, the magnetizations 154 of neighboring grains 152 may more freely respond to a spin-transfer torque.

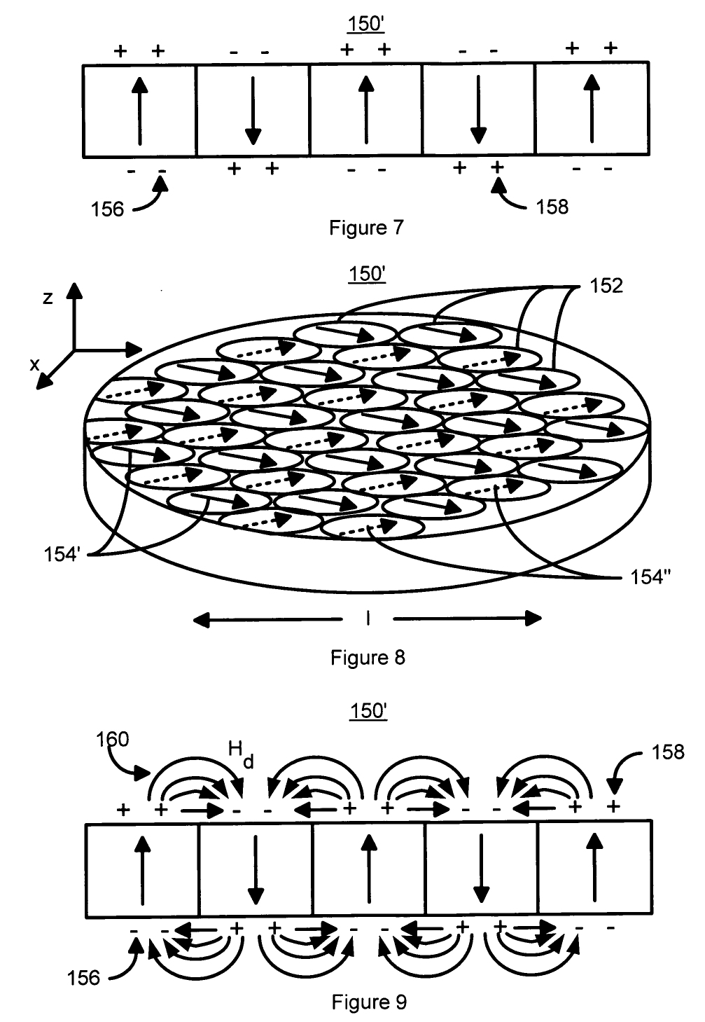

A write current may be applied to the granular free layer 150. This is preferably accomplished by applying a current to the magnetic element (the remainder of which is not shown) incorporating the granular free layer 150 in a CPP configuration. Consequently, the granular free layer 150 may undergo switching due to the spin-transfer effect. During spin-transfer based switching, the magnetization 151 of the free layer 150 experiences spin-transfer torque. This torque, along with the anisotropy field, can bring the magnetizations 154 of at least some of the grains 152 in the ferromagnetic granular layer 150 out of plane. Because the magnetizations 154 of the grains 152 are not strongly bound, they are expected to form a checkerboard-type pattern during switching. FIG. 7 depicts the granular free layer 150′ during switching. Thus, the checkerboard-type pattern of alternating positive charges 158 and negative charges 156 formed on the surface of the granular free layer 150′ is shown. Note that for simplicity and clarity only the vertical components of the magnetizations are depicted in FIG. 7. FIG. 8 also depicts the granular free layer 150′ during switching. The dashed arrows depict magnetizations 154″ pointing slightly up (small positive z component), while the black arrows depict magnetizations 154″ pointing slightly down (small negative z component). This checkerboard-type pattern has lower magnetostatic energy than the uniform magnetization distribution as in the case of a conventional ferromagnetic free layer. As a result of such a distribution of magnetizations 154′ and 154″, partial cancellation of magnetostatic charges on the surface of the granular free layer 150′ is observed and shown in FIG. 7. The resulting demagnetizing field 160 is shown in FIG. 9. Note that for simplicity and clarity only the vertical components of the magnetizations are depicted in FIG. 9. The demagnetizing field 160 allows for flux closure and greatly reduced demagnetizing field in the granular free layer 150. This reduced effective out-of-plane demagnetizing field results in greatly decreased switching current density, as follows from equation (1). Thus, the granular free layer 150 may be switched at a lower current density.

The situation described above is in contrast to switching of a conventional free layer 18/18′. FIGS. 10-12 depict a conventional free layer during switching. FIG. 10 depicts the conventional free layer 180 at equilibrium. The conventional free layer 180 is analogous to the conventional free layer 18/18′. The local magnetizations 182 are almost uniform for the ferromagnetic layer 18/18′, which typically has a strong exchange coupling. During spin-transfer switching, the magnetization of the conventional free layer 180 experiences spin-transfer torque. This torque, along with the anisotropy field, can bring the magnetizations 182 ferromagnetic free layer 180 out of plane. This induces very strong out-of-plane demagnetizing field. This out-of-plane motion is the source of H_{d}/2 term in equation (1) for the critical current density, above.

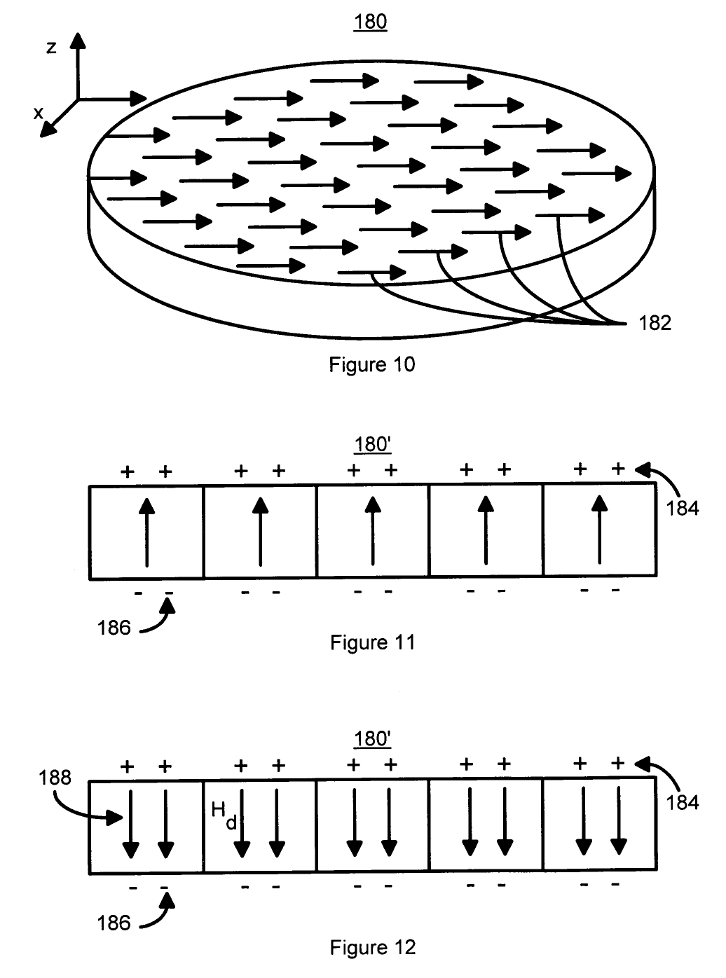

The out-of-plane motion creates non-compensated charges on the surface of the free layer 180. This situation is depicted in FIG. 11. FIG. 11 depicts the charges 184 and 186 formed on the surface of the conventional free layer 180′ during switching. These charges 184 and 186 result in strong out-of-plane demagnetizing field. This demagnetizing field 188, H_{d}, is depicted in FIG. 12. The demagnetizing field 188 is closely approximated by 4πMₛ and is generally in the range of approximately 10,000 Oe. This value is typically much higher than the external field H, which is usually less than fifty Oe and anisotropy field Hₖ, which is typically on the order of one hundred to three hundred Oe. Consequently, as can be seen in equation (1), the demagnetizing field 188 may limit the achievable reduction in switching current density J_{c0}. Thus, the granular free layer 150 may be written utilizing spin-transfer at a lower current density than a conventional free layer 180.

In order to read the magnetic elements 100 and 100′, a read current is driven through the magnetic elements 100 and 100′. The read current is preferably less than the write current in order to avoid inadvertently writing to the magnetic element 100/100′. Based on the resistance of the magnetic element 100 or 100′, the state (P or AP) of the magnetic element 100 or 100′ can be determined.

Thus, the magnetic elements 100 and 100′ having granular free layers 130 and 130′ may be switched at a lower current density than a conventional free layer tunneling barrier breakdown during switching for a magnetic element 100/100′ employing a non-conductive spacer layer 120. Further, the use of the magnetic element 100/100′ in a magnetic memory may decrease the size of the transistor connected in series with the magnetic element 100/100′ to form a memory cell in some implementations.

Furthermore, the granular free layers 130, 130′, and 150 may have an improved thermal stability that is less subject to variations in processing. The thermal stability of the granular free layers 130, 130′ and 150 is primarily due to the intrinsic anisotropy field of a grain 134 and 152 and exchange interaction between the grains 134 and 152. As a result, there is generally only a marginal dependence on the shape or lateral dimensions of the free layer 130, 130′ and 150 itself. Instead, there is a dependence of the thermal stability factor on the size and aspect ratio of grains 134 and 152, as well as the composition of the granular free layer 130, 130′, and 150. These features are expected to be controlled during the deposition with higher accuracy than the dimensions of the magnetic element 100 and 100′ can be controlled during patterning. Consequently, the thermal stability of the magnetic elements 100 and 100′ may be improved, and the magnetic devices may be less subject to variations in processing. Moreover, magnetic devices may be less sensitive to temperature and external field disturbance and may have reduced incidences of unwritten or accidentally written cells in a memory.

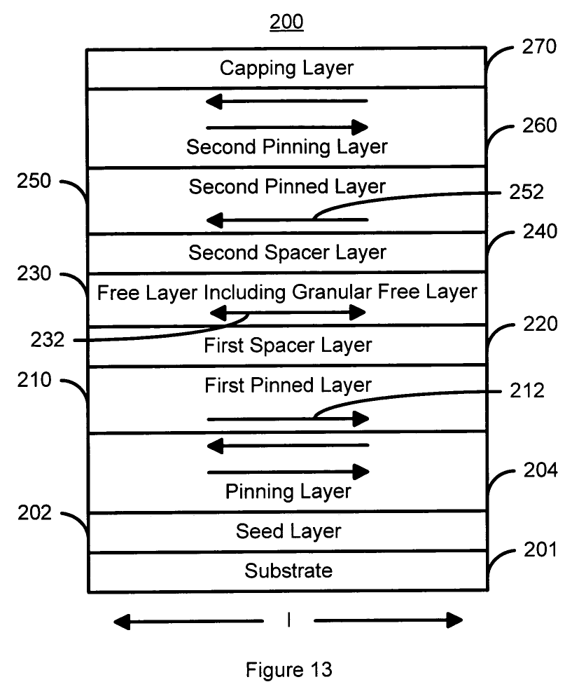

FIG. 13 is a diagram of another embodiment of a magnetic element 200 capable of being switched using spin-transfer and including a granular free layer. The magnetic element 200 includes a first pinned layer 210, a first spacer layer 220, a free layer 230, a second spacer layer 240, and a second pinned layer 250. In addition, the magnetic element 200 may include a seed layer 202, a first pinning layer 204, a second pinning layer 260, and a capping layer 270. Also depicted is a substrate 201 on which the magnetic element 200 is formed.

The pinning layers 204 and 260 are preferably antiferromagnetic (AFM) layers, for example including PtMn and/or IrMn. The pinning layers 204 and 260 are used to pin the magnetizations 212 and 252, respectively, of the pinned layers 210 and 250, respectively, in desired directions. However, in another embodiment, another mechanism might be used for pinning the magnetization 212 and/or the magnetization 252 in the desired direction(s).

The pinned layers 210 and 250 each preferably includes at least one of Co, Ni, and Fe. The pinned layers 210 and 250 each has its magnetization 212 and 252, respectively, pinned in the desired direction, which is preferably along the easy axis of the free layer 230. The pinned layers 210 and 250 are shown as simple layers. However, the pinned layer 210 and/or the pinned layer 250 may be multilayers. For example, the pinned layer 210 and/or the pinned layer 250 may be a SAF layer including two ferromagnetic layers separated by a thin non-magnetic conductive layer, such as Ru. The ferromagnetic layers for such an SAF preferably have their magnetizations aligned antiparallel. Also in a preferred embodiment, the magnetizations 212 and 252 are pinned in opposite directions, as shown in FIG. 13. Note however, that there are barriers to fabricating this configuration, with both pinned layers 210 and 250 being simple and having their magnetizations 212 and 252, respectively, aligned antiparallel. Consequently, in a preferred embodiment the second pinned layer 250 is simple, while the first pinned layer 210 is an SAF with the ferromagnetic layer closest to the first spacer layer 220 having its magnetization antiparallel to the magnetization 252 of the second pinned layer 250.

The spacer layers 220 and 240 are nonmagnetic and may be conductive, insulating, or a nano-oxide layer. For example, if the spacer layer 220 and/or the spacer layer 250 are conductive, conductive materials such as Cu might be used. If the spacer layer 220 and/or the spacer layer 240 is insulating, the spacer layer 220 and/or the spacer layer 250 is thin. Consequently, current carriers may tunnel through the spacer layer 220 and/or the spacer layer 240. Insulating materials used may include materials such as alumina and/or crystalline MgO.

The free layer 230 is configured to be switched using spin-transfer. In addition, the free layer 230 includes a granular free layer. In the embodiment shown, the free layer 230 consists of a granular free layer. The free layer 230 is, therefore, analogous to the free layers 130, 130′, and 150. Consequently, the free layer 230 includes grains (not explicitly shown in FIG. 13) in a matrix (not explicitly shown in FIG. 13). The magnetization 232 of the granular free layer 230 is aligned with the easy axis, 1, of the granular free layer 230. The magnetization 232 of the granular free layer 230 is established by the net magnetization of the grains. Similarly, the easy axis of the granular free layer 230 is established by the grains. Thus, in a preferred embodiment, the grains in the granular free layer 230 are elongated along the easy axis to create uniaxial anisotropy along this direction (to the left or right as shown in FIG. 13). Thus, the grains are longer in a direction parallel to the easy axis, 1, and have an aspect ratio greater than one. In a preferred embodiment, the aspect ratio of the grains is at least two and not greater than ten. However, in an alternate embodiment, the aspect ratio may be greater than ten, for example to maintain the thermal stability of the grains. The longitudinal size (length parallel to the easy axis) of the grains is preferably from five to fifty nanometers. The exchange stiffness constant for the exchange interaction between the grains is preferably less than the intra-granular exchange stiffness constant. Consequently, the magnetization of the neighboring grains may have different orientation during the spin-transfer switching, described below. In addition, the discussion above is in the context of all of the grains. However, one of ordinary skill in the art will readily recognize that the description above, such as the aspect ratio, need not apply to all grains. In one embodiment, the discussion above applies to a majority of the grains. In a preferred embodiment, the discussion above applies to substantially all of the grains.

The granular free layer 230 can be formed using a variety of types of materials. In general, the material(s) are used for the grains are immiscible with the material(s) used for the matrix. The granular free layer 230 might be metallic-based, oxide-based, multilayer-granular, and/or may be formed of other materials. For example, if the granular free layer 230 is metallic based, the granular free layer 230 may include TMₓNM₍₁₀₀₋ₓ₎, where the TM includes at least one of Ni, Fe, and Co, NM includes at least one of Cu, Ag, and Au, and x is at least five and not more than fifty atomic percent. Similarly, if the granular free layer 230 is metallic based, the granular free layer 230 may include (TM1_{y}TM2_{(1-y)})ₓNM₍₁₀₀₋ₓ₎ where the TM1 includes at least one of Ni, Fe, and Co, the TM2 is at least one of Ni, Fe, Co, NM includes at least one of Cu, Ag, Au, x is at least five and not more than fifty atomic percent, and y is at least 0.05 and not more than 0.95. If the granular free layer 230 is metallic based, the granular free layer 230 may include the granular free layer includes (CoFeNi)ₓNM₍₁₀₀₋ₓ₎, where the NM includes at least one of Cu, Ag, and Au and x is at least five and not more than fifty atomic percent. If the granular free layer 230 is oxide based, the granular free layer 230 may include TM_{y}Oxide_{(100-y)}, where the TM includes at least one of Ni, Fe, Co, the Oxide includes at least one of AlOₓ, SiOₓ, TiOₓ, TaOₓ, ZrOₓ, HfOₓ, MgO; and y is at least five and not more than fifty atomic percent. Similarly, if the granular free layer 230 is oxide based, the granular free layer 230 may include (TM1_{z}TM2_{(1-z)})_{y}Oxide_{(100-y)}, where TM1 is at least one of Ni, Fe, and Co, TM2 is at least one of Ni, Fe, Co, the Oxide includes at least one of AlOₓ, SiOₓ, TiOₓ, TaOₓ, ZrOₓ, HfOₓ, and MgO; y is at least five and not more than fifty atomic percent and z is at least 0.05 and not more than 0.95. If the granular free layer 230 is oxide based, the granular free layer 230 may include (CoFeNi)_{y}Oxide_{(100-y)}, where the Oxide includes at least one of AlOₓ, SiOₓ, TiOₓ, TaOₓ, ZrOₓ, HfOₓ, and MgO, and y is at least five and not more than fifty atomic percent.

In addition, the granular free layer 230 may be a multilayer. In such an embodiment, the granular free layer 230 may include a bilayer that might be repeated multiple times. In such an embodiment, the bilayer includes a first layer and a second layer. The first layer includes a transition metal at a first thickness, while the second layer is nonmagnetic and has a second thickness. In a preferred embodiment, the first thickness is at least five Angstroms and not more than one hundred Angstroms and wherein the second thickness is at least ten Angstroms and not more than one hundred Angstroms. In such an embodiment, the first layer includes a transition metal. Thus, the first layer may be a transition metal alloy. The second layer includes at least one of Cu, Ag, Au, AlOₓ, SiOₓ, TiOₓ, TaOₓ, ZrOₓ, HfOₓ, and MgO. In addition, note that the granular free layer may include materials such as CrFe. Moreover, certain of the granular systems described above may have a perpendicular anisotropy. For example, the use of CoFe—HfO, CoFe—AgCu, CoPt—SiO₂ and/or CoPtCr—SiO₂ granular layers 230 may assist in increasing spin-transfer effect. The granular free layer 230 may also be CrFe.

The granular free layer 230 may include any combination of the materials and layers described above. For example, if the granular free layer 230 includes a metallic matrix (either as described above or as part of the multilayer described above), the matrix may be a binary or ternary alloy for example of Cu, Ag, and Au. An oxide matrix can be a mixture of two or more oxides out of those above.

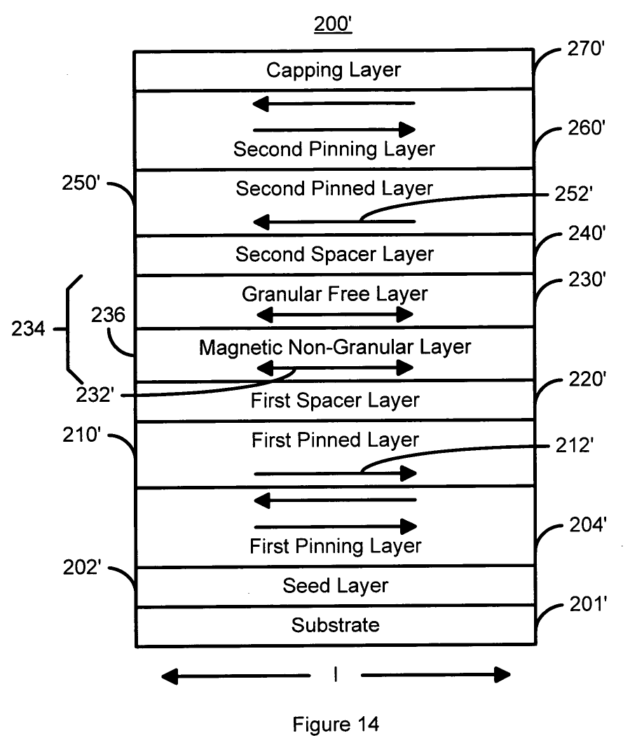

FIG. 14 is a diagram of another embodiment of a magnetic element 200′ capable of being switched using spin-transfer and including a granular free layer. The magnetic element 200′ is analogous to the magnetic element 200. Consequently, analogous components are labeled similarly. Thus, the magnetic element 200′ includes layers 202′, 204′, 210′, 230′, 240′, 250′, 260′, and 270′.

The granular free layer 230′ can be switched using spin-transfer and is part of the free layer 234. The free layer 234 thus includes the granular free layer 230′ and at least one other layer. In the embodiment shown, the other layer is a magnetic layer 236. The magnetic layer 236 can also be switched using spin-transfer and is not a granular layer. Consequently, the magnetic layer 236 and, preferably, the entire free layer 234 may have the lateral dimensions, along the long axis, of the free layer 234 that are small and preferably less than two hundred nanometers. In a preferred embodiment, the magnetic layer 236 includes at least one of CoFe and CoFeB. Also in a preferred embodiment, the magnetic layer 236 has a thickness from three Angstroms to ten Angstroms. Such a magnetic layer 236 may enhance the tunneling magnetoresistance.

In operation, the magnetic elements 200 and 200′ are written and read in a similar manner to the magnetic elements 100 and 100′. The magnetic elements 200 and 200′ are analogous to and have many of the same advantages as the magnetic elements 100 and 100′. For example, the magnetic elements 200 and 200′ may be written using spin-transfer at a lower current density. The magnetic elements 200 and 200′ may also exhibit improved stability, less variation with variations in processing, and reduced issues due to unwritten or accidentally written cells. Furthermore, the magnetic elements 200 and 200′ may be written at an even lower write current because the spin-transfer from the pinned layers 210 and 250 may contribute if the magnetizations 212 and 252 are properly aligned. Moreover, the magnetic elements 200 and 200′ exhibit a decreased partial magnetoresistance cancellation. Consequently, the signal for the magnetic elements 200 and 200′ may be improved. The signal may also be increased for the magnetic element 200′ because the magnetoresistance between the granular free layer 230′ and the second pinned layer 250′ is expected to be less than the magnetoresistance between the ferromagnetic free layer 236 and the first pinned layer 210′.

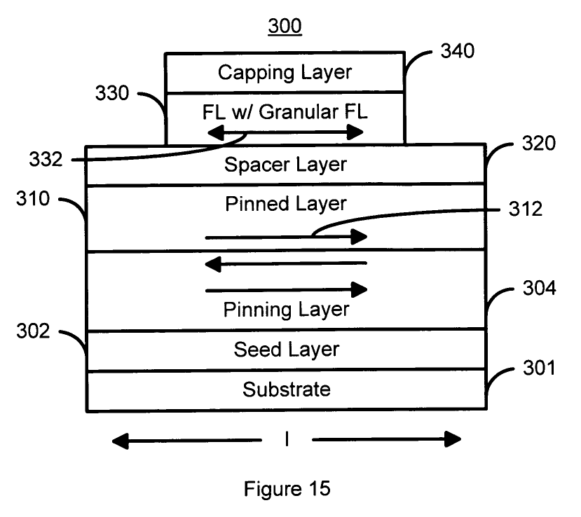

FIG. 15 is a diagram of another embodiment of a magnetic element 300 capable of being switched using spin-transfer and including a granular free layer. The magnetic element 300 is analogous to the magnetic elements 100/100′ and thus includes at least a pinned layer 310, a spacer layer 320, and a free layer 330 that are analogous to the layers 110/110′, 120/120′, and 130/138 in the magnetic element 100/100′. The magnetic element 300 also includes a seed layer 302, a pinning layer 304 analogous to the pinning layers 104 and 104′.

Thus, the free layer 330 includes a granular free layer and can be switched utilizing spin-transfer. In one embodiment, the free layer 330 consists of the granular free layer such that the magnetic element 300 is analogous to the magnetic element 100. In another embodiment, the free layer 330 includes a granular free layer and at least one other layer, such as a non-granular magnetic element. In one such embodiment, the free layer 330 is analogous to the free layer 138 so that the magnetic element 300 is analogous to the magnetic element 100′. However, the free layer 330 and layers above the free layer 330, such as the capping layer 340 have smaller lateral dimensions than the layers 302, 304, 310, and 320 below the free layer 330. If the free layer 330 consists of a granular free layer, then the granular free layer has smaller lateral dimensions than the layers 302, 304, 310, and 320 below. Similarly, if the free layer 330 is a combination of a granular free layer and other layer(s), both the granular free layer and the other layer(s) preferably have a smaller dimension than the underlying layers 302, 304, 310, and 320.

The magnetic element 300 shares the benefits of the magnetic elements 100 and 100′. In addition, because the free layer 330 has smaller lateral dimensions than at least the layer 320 and preferably all of the underlying layers 302, 304, 310, and 320, there may be a reduced probability of shorting between the free layer 330 and the pinned layer 310. Consequently, fabrication and reliability of the magnetic element 300 may be improved.

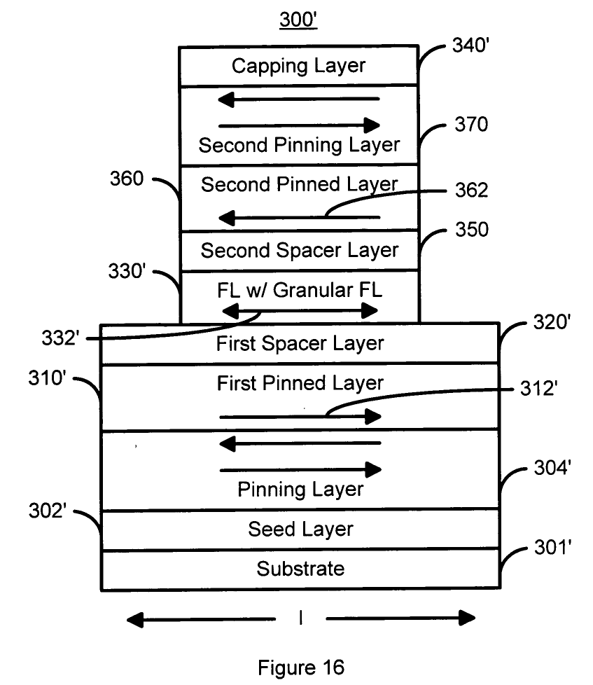

FIG. 16 is a diagram of another embodiment of a magnetic element 300′ capable of being switched using spin-transfer and including a granular free layer. The magnetic element 300′ is analogous to the magnetic elements 300, 200, and 200′. Thus, the magnetic element 300′ includes at least a pinned layer 310′, a spacer layer 320′, a free layer 330′, a second spacer layer 350, and a second pinned layer 360 that are analogous to the layers 310/210/210′, 320/220/220′, and 330/230/234 in the magnetic elements 300/200/200′. The magnetic element 300′ also includes a seed layer 302′, a first pinning layer 304′ analogous to the pinning layers 304/204/204′, a second pinning layer 370 analogous to pining layers 260/260′, and a capping layer 340′analogous to capping layers 340/270/270′.

Thus, the free layer 330′ includes a granular free layer and may be switched using spin-transfer. In one embodiment, the free layer 330′ consists of the granular free layer such that the magnetic element 300′ is analogous to the magnetic element 200. In another embodiment, the free layer 330′ includes a granular free layer and at least another layer, such as a non-granular magnetic element. In one such embodiment, the free layer 330′ is analogous to the free layer 234 so that the magnetic element 300′ is analogous to the magnetic element 200′. However, the free layer 330′ and layers above the free layer 330′, such as the second spacer layer 350, the second pinned layer 360, the second pinning layer 370, and the capping layer 340′ have smaller lateral dimensions than the layers 302′,304′,310′, and 320′ below the free layer 330′. If the free layer 330′ consists of a granular free layer, then the granular free layer has smaller lateral dimensions than the layers 302′, 304′, 310′, and 320′below. Similarly, if the free layer 330′ is a combination of a granular free layer and other layer(s), both the granular free layer and the other layer(s) preferably have a smaller dimension than the underlying layers 302′, 304′, 310′, and 320′.

The magnetic element 300′ shares the benefits of the magnetic elements 200, 200′, and 300. Because the free layer 330′ has smaller lateral dimensions than at least the layer 320′ and preferably all of the underlying layers 302′, 304′, 310′, and 320′, there may be a reduced probability of shorting between the free layer 330′ and the pinned layer 310′. Moreover, because a dual structure is provided, signal and spin-transfer switching may be further improved. Consequently, fabrication and reliability of the magnetic element 300′ may be improved.

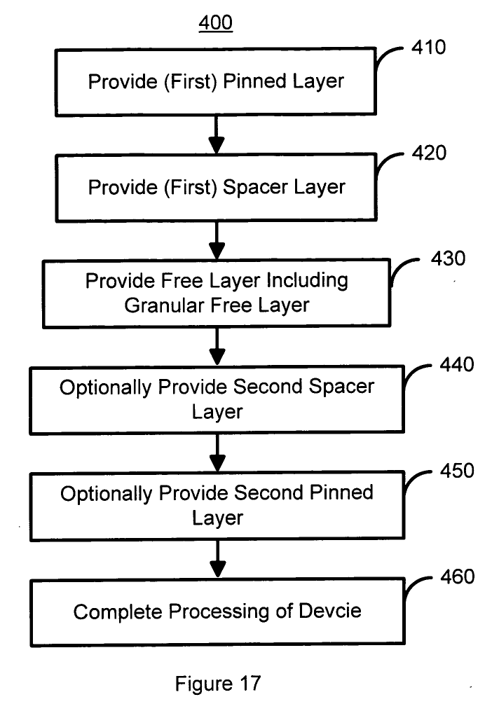

FIG. 17 is a flow chart depicting one embodiment of a method 400 in accordance with the present invention for providing one embodiment of a magnetic element capable of being switched using spin-transfer and including a granular free layer. One of ordinary skill in the art will readily recognize that for ease of explanation, steps may be omitted and/or combined.

The pinned layer 110/110′/210/210′/310/310′ is provided, via step 410. Step 410 may include providing a simple pinned layer 110/110′/210/210′/310/310′ or providing a multilayer such as an SAF. The spacer layer 120/120′/220/220′/320/320′ is provided, via step 420. The spacer layer 120/120′/220/220′/320/320′ may be conductive, insulating, or a nano-oxide layer, as described above. The free layer 130/138/230/234/330/330′ including a granular free layer 130/130′/230/230′/330/330′ is provided, via step 430. In addition, for the magnetic element 300/300′, step 430 may include ensuring that the free layer 330/330′ has smaller lateral dimensions than underlying layers. This may include masking portions of the underlying layers or etching the free layer 330/330′ at some time, preferably after subsequent layers are formed. Note that if the magnetic elements 100, 100′, and/or 300 are being provided, the method may essentially terminate at step 430, with certain exceptions, such as providing a capping layer 140/140′/340 and completing fabrication of the device. However, for a dual structure, such as the magnetic elements 200/200′/300′, a second spacer layer 240/240′/350 is provided, via step 440. Step 440 may include providing a conductive, insulating, or nano-oxide spacer layer 240/240′/350. For the magnetic element 300′, step 440 may include ensuring that the spacer layer 350 has smaller lateral dimensions than underlying layers. This may include using a mask provided for the free layer 330′ or etching the layer 350 at some time, preferably after subsequent layers are formed. The second pinned layer 250/250′/360 may be provided for a dual structure, via step 450. Step 450 may include providing a simple pinned layer 250/250′/360 or providing a multilayer such as an SAF. For the magnetic element 300′, step 450 may include ensuring that the second pinned layer 360 has smaller lateral dimensions than underlying layers. This may include using a mask provided for the free layer 330′ or etching the layer 360 at some time, preferably after subsequent layers are formed. Fabrication is completed, via step 460. Step 460 may include providing a capping layer 140/140′/270/270′/340/340′, as well as providing other structures used in the device, such as transistors and conductive lines.

Thus, using the method 400, the magnetic elements 100, 100′, 200, 200′, 300, and/or 300′. Consequently, the benefits of the magnetic elements 100, 100′, 200, 200′, 300, and/or 300′ can be achieved.

A method and system for providing and using a magnetic element has been disclosed. The present invention has been described in accordance with the embodiments shown, and one of ordinary skill in the art will readily recognize that there could be variations to the embodiments, and any variations would be within the spirit and scope of the present invention. Accordingly, many modifications may be made by one of ordinary skill in the art without departing from the spirit and scope of the appended claims.

We claim:

1. A magnetic element comprising:
a pinned layer;
a spacer layer;
a free layer including granular free layer having a plurality of grains in a matrix, the spacer layer residing between the pinned layer and the free layer.
wherein the magnetic element is configured to allow the granular free layer to be switched due to spin-transfer when a write current is passed through the magnetic element.

2. The magnetic element of claim 1 wherein a majority of the plurality of grains have an aspect ratio greater than one.

3. The magnetic element of claim 2 wherein the aspect ratio is at least two.

4. The magnetic element of claim 3 wherein the aspect ratio is not more than ten.

5. The magnetic element of claim 2 wherein the majority of the plurality of grains have a longitudinal size of not more than fifty nanometers.

6. The magnetic element of claim 2 wherein the majority of the plurality of grains have a longitudinal size of at least five nanometers.

7. The magnetic element of claim 1 wherein the plurality of grains includes a plurality of ferromagnetic grains and the matrix is an oxide and/or metallic matrix.

8. The magnetic element of claim 1 wherein the granular free layer includes TMₓNM₍₁₀₀₋ₓ₎, where the TM includes at least one of Ni, Fe, and Co, NM includes at least one of Cu, Ag, and Au, and x is at least five and not more than fifty atomic percent.

9. The magnetic element of claim 1 wherein the granular free layer includes (TM1_{y}TM2_{(1-y)})ₓNM₍₁₀₀₋ₓ₎ where the TM1 includes at least one of Ni, Fe, and Co, the TM2 is at least one of Ni, Fe, Co, NM includes at least one of Cu, Ag, Au, x is at least five and not more than fifty atomic percent, and y is at least 0.05 and not more than 0.95.

10. The magnetic element of claim 1 wherein the granular free layer includes (CoFeNi)ₓNM₍₁₀₀₋ₓ₎, where the NM includes at least one of Cu, Ag, and Au and x is at least five and not more than fifty atomic percent.

11. The magnetic element of claim 1 wherein the granular free layer includes TM_{Y}Oxide_{(100-y)}, where the TM includes at least one of Ni, Fe, Co, the Oxide includes at least one of AlOₓ, SiOₓ, TiOₓ, TaOₓ, ZrOₓ, HfOₓ, MgO; and y is at least five and not more than fifty atomic percent.

12. The magnetic element of claim 1 wherein the granular free layer includes (TM1_{z}TM2_{(1-z)})_{y}Oxide_{(100-y)}, where TM1 is at least one of Ni, Fe, and Co, TM2 is at least one of Ni, Fe, Co, the Oxide includes at least one of AlOₓ, SiOₓ, TiO_{x, TaO}ₓ, ZrOₓ, HfOₓ, and MgO; y is at least five and not more than fifty atomic percent and z is at least 0.05 and not more than 0.95.

13. The magnetic element of claim 1 wherein the granular free layer includes (CoFeNi)_{y}Oxide_{(100-y)}, where the Oxide includes at least one of AlOₓ, SiOₓ, TiOₓ, TaOₓ, ZrOₓ, HfOₓ, and MgO, and y is at least five and not more than fifty atomic percent.

14. The magnetic element of claim 1 wherein the granular free layer is a multilayer includes a bilayer having a first layer and a second layer.

15. The magnetic element of claim 14 wherein the first layer includes a transition metal at a first thickness the second layer is nonmagnetic and has a second thickness.

16. The magnetic element of claim 15 wherein the first thickness is at least five Angstroms and not more than one hundred Angstroms and wherein the second thickness is at least ten Angstroms and not more than one hundred Angstroms.

17. The magnetic element of claim 15 wherein the transition metal is a transition metal alloy.

18. The magnetic element of claim 15 wherein the second layer includes at least one of Cu, Ag, Au, AlOₓ, SiOₓ, TiOₓ, TaOₓ, ZrOₓ, HfOₓ, and MgO.

19. The magnetic element of claim 14 wherein the multilayer includes the bilayer repeated at least once.

20. The magnetic element of claim 1 wherein the free layer further includes a magnetic, non-granular layer.

21. The magnetic element of claim 20 wherein the magnetic non-granular layer includes CoFe or CoFeB having a thickness of at least three Angstroms and not more than ten Angstroms.

22. The magnetic element of claim 1 wherein the granular free layer further includes at least one of CoFe—HfO, CoFe—AgCu, CoPt—SiO₂, CoPtCr—SiO₂, and CrFe.

23. The magnetic element of claim 1 wherein the free layer resides above the pinned layer.

24. The magnetic element of claim 23 wherein the pinned layer has a first cross-sectional area and the free layer has a second cross-sectional area smaller than the first cross-sectional area.

25. The magnetic element of claim I wherein an exchange stiffness constant for an exchange interaction between the majority of the plurality of grains is less than an intra granular exchange stiffness constant for the majority of the plurality of grains.

26. The magnetic element of claim 1 wherein the pinned layer is a synthetic antiferromagnetic layer including a first ferromagnetic layer, a second ferromagnetic layer, and a nonmagnetic conductive layer residing between the first ferromagnetic layer and the second ferromagnetic layer.

27. The magnetic element of claim 26 wherein the first ferromagnetic layer and the second ferromagnetic layer include at least one of Co, Ni, and Fe.

28. The magnetic element of claim 1 wherein the spacer layer is an insulating barrier layer.

29. The magnetic element of claim 28 wherein the insulating barrier layer includes at least one of alumina and crystalline MgO.

30. The magnetic element of claim 1 wherein the spacer layer includes a conductor or a nano-oxide layer.

31. The magnetic element of claim 1 further comprising:
an additional spacer layer; and
an additional pinned layer, the additional spacer layer residing between the free layer and the additional pinned layer.

32. The magnetic element of claim 31 wherein a majority of the plurality of grains have an aspect ratio greater than one.

33. The magnetic element of claim 32 wherein the aspect ratio is at least two.

34. The magnetic element of claim 33 wherein the aspect ratio is not more than ten.

35. The magnetic element of claim 32 wherein the majority of the plurality of grains have a longitudinal size of not more than fifty nanometers.

36. The magnetic element of claim 32 wherein the majority of the plurality of grains have a longitudinal size of at least five nanometers.

37. The magnetic element of claim 32 wherein the granular free layer is a multilayer.

38. The magnetic element of claim 37 wherein the multilayer includes a bilayer having a first layer and a second layer, the first layer includes a transition metal at a first thickness the second layer is nonmagnetic and has a second thickness.

39. The magnetic element of claim 38 wherein the first thickness is at least five Angstroms and not more than one hundred Angstroms and wherein the second thickness is at least ten Angstroms and not more than one hundred Angstroms.

40. The magnetic element of claim 39 wherein the transition metal is a transition metal alloy.

41. The magnetic element of claim 39 wherein the second layer includes at least one of Cu, Ag, Au, AlOₓ, SiOₓ, TiOₓ, TaOₓ, ZrOₓ, HfOₓ, and MgO.

42. The magnetic element of claim 38 wherein the multilayer includes the bilayer repeated at least once.

43. The magnetic element of claim 31 wherein the free layer further includes a magnetic, non-granular layer.

44. The magnetic element of claim 43 wherein the magnetic non-granular layer includes CoFe or CoFeB having a thickness of at least three Angstroms and not more than ten Angstroms.

45. The magnetic element of claim 31 wherein the granular free layer further includes at least one of CoFe—HfO, CoFe—AgCu, CoPt—SiO₂, CoPtCr—SiO₂, and CrFe.

46. The magnetic element of claim 31 wherein the free layer resides above the pinned layer.

47. The magnetic element of claim 46 wherein the pinned layer has a first cross-sectional area and the free layer has a second cross-sectional area smaller than the first cross-sectional area.

48. The magnetic element of claim 31 wherein an exchange stiffness constant for an exchange interaction between the majority of the plurality of grains is less than an intra granular exchange stiffness constant for the majority of the plurality of grains.

49. The magnetic element of claim 31 wherein the pinned layer is a synthetic antiferromagnetic layer including a first ferromagnetic layer, a second ferromagnetic layer, and a nonmagnetic conductive layer residing between the first ferromagnetic layer and the second ferromagnetic layer.

50. The magnetic element of claim 49 wherein the first ferromagnetic layer and the second ferromagnetic layer include at least one of Co, Ni, and Fe.

51. The magnetic element of claim 31 wherein the spacer layer is an insulating barrier layer.

52. The magnetic element of claim 51 wherein the insulating barrier layer includes at least one of alumina and crystalline MgO.

53. The magnetic element of claim 31 wherein the spacer layer includes a conductor or a nano-oxide layer.

54. A magnetic element comprising:
a pinned layer;
a spacer layer;
a free layer including granular free layer having a plurality of grains in a matrix;
wherein the magnetic element is configured to allow the granular free layer to be switched due to spin-transfer when a write current is passed through the magnetic element; wherein a majority of the plurality of grains have an aspect ratio of at least two and less than or equal to ten; wherein the majority of the plurality of grains have a longitudinal size of at lest five nanometers and not more than fifty nanometers, and wherein an exchange stiffness constant for an exchange interaction between the majority of the plurality of grains is less than an intra granular exchange stiffness constant for the majority of the plurality of grains.

55. The magnetic element of claim 54 wherein the pinned layer has a first cross-sectional area and the free layer has a second cross-sectional area smaller than the first cross-sectional area.

56. The magnetic element of claim 54 wherein the pinned layer is a synthetic antiferromagnetic layer including a first ferromagnetic layer, a second ferromagnetic layer, and a nonmagnetic conductive layer residing between the first ferromagnetic layer and the second ferromagnetic layer.

57. A magnetic memory comprising:
a plurality of magnetic memory cells, each of the plurality of magnetic memory cells including at lest one magnetic element; each of the at least one magnetic element including a first pinned layer, a spacer layer, and a free layer including granular free layer having a plurality of grains in a matrix, wherein the magnetic element is configured to allow the granular free layer to be switched due to spin-transfer when a write current is passed through the magnetic element; wherein a majority of the plurality of grains have an aspect ratio of at least two and less than or equal to ten; wherein the majority of the plurality of grains have a longitudinal size of at lest five nanometers and not more than fifty nanometers; and
a plurality of conductive lines coupled with the plurality of memory cells.
